(19) United States
(12) Patent Application Publication
(10) Pub. No.: US 2026/0081401 A1
(43) Pub. Date: Mar. 19, 2026

(54) Integrated Laser Stabilization with Built-In Isolation

(71) Applicant: The Board of Trustees of the Leland Stanford Junior University, Stanford, CA (US)

(72) Inventors: Alexander White, Burlingame, CA (US); Geun Ho Ahn, Redwood City, CA (US); Kasper Van Gasse, Ghent (BE); Jelena Vuckovic, Palo Alto, CA (US)

(21) Appl. No.: 19/108,497

(22) PCT Filed: Sep. 8, 2023
(86) PCT No.: PCT/US2023/032287

§ 371 Date: Mar. 4, 2025

Related U.S. Application Data
(60) Provisional application No. 63/405,288, filed on Sep. 9, 2022.

(51) Int. Cl. H01S 5/14; G02F 1/35; G02F 1/365; H01S 5/0687

(52) U.S. Cl. CPC H01S 5/142; G02F 1/3521; G02F 1/365; H01S 5/0687

(57) ABSTRACT

Laser feedback stabilization combined with isolation is provided in an integrated approach. The main element is a high quality factor resonator that acts as a circulator under high optical power due to the Kerr nonlinearity. This resonator can then be coupled to a laser or optical gain media to provide isolation and combined with a feedback path to stabilize the lasing mode.

### FIELD OF THE INVENTION

This invention relates to combined isolation and feedback stabilization of lasers.

### BACKGROUND

In many applications, lasers need feedback stabilization and isolation—yet both of these processes are difficult to achieve in an integrated fashion, adding complexity and bulk to laser systems. For example, optical isolators often rely on the Faraday effect in magnetooptic materials, but such materials are typically difficult to integrate with standard photonic integrated circuit materials, and providing the required magnetic field is also difficult to do with an integration technology. As another example, laser feedback stabilization often requires active control, especially during startup, and the required components for this can undesirably increase the complexity of any photonic integrated circuit that includes them. Accordingly, it would be an advance in the art to provide laser isolation and feedback stabilization that is more amenable to integration.

### SUMMARY

This work solves this problem by combining the laser feedback stabilization and isolator into a single integrated device. This approach includes an integrated photonic device that uses waveguides and resonators to isolate and stabilize a laser. The main element of these devices is a high quality factor ring or disk resonator that acts as a circulator under high optical power due to the Kerr nonlinearity. This ring can then be coupled to a laser or optical gain media and combined with a feedback path to stabilize the lasing mode.

Integrated lasers that need both stabilization and isolation serve as a major backbone of the internet. By simplifying and integrating the stabilization and isolation, the cost for data communication systems can be reduced and the performance can be enhanced. Furthermore, this new capability opens up commercial possibilities in lidar, spectroscopy, and mobile optical computing. While there are several methods for laser feedback stabilization and for integrated isolation, there is not currently a scheme that combines both. This adds significant complexity for integrating both with a laser, and because of this we are not aware of any laser with integrated stabilization and isolation. Our method provides a simple solution that allows for direct integration of both.

### BRIEF DESCRIPTION OF THE DRAWINGS

FIG. 1 shows the operating principle of nonlinear nonreciprocal ring resonators for providing isolation.

FIGS. 2A-C show three exemplary embodiments of the invention.

FIG. 3 shows measured isolation performance of a nonlinear ring resonator.

FIG. 4 shows measured laser noise suppression in an embodiment of the invention.

### DETAILED DESCRIPTION

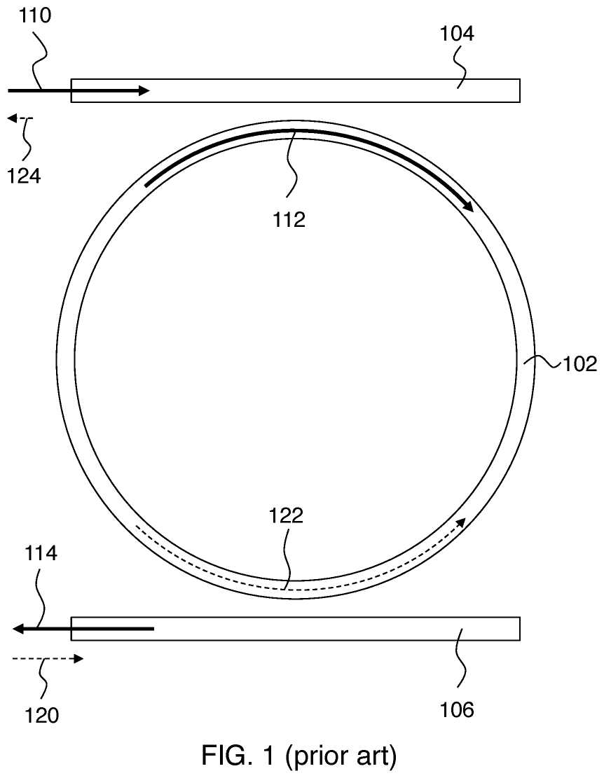

FIG. 1 shows the operating principle of nonlinear nonreciprocal ring resonators for providing isolation. In this example, a ring resonator 102 is a Kerr effect medium having an intensity-dependent index of refraction. Optical input light 110 in first waveguide 104 couples to clockwise mode 112 in ring resonator 102. This light is then coupled to second waveguide 106 and is emitted as output light 114. If there is an output back-reflection 120, it propagates in second waveguide 106, propagates counter-clockwise in ring resonator 102 (as schematically shown by 122), and is then emitted from first waveguide 104 as input back-reflection 124.

Because of the Kerr effect, the mode spectra of clockwise and counterclockwise modes in ring resonator 102 are different for sufficiently large circulating power, so it is possible to arrange things so that ring resonator 102 is on-resonance for clockwise mode 112 and is off resonance for counter-clockwise propagation 122 at the same frequency. Note that a back-reflection is necessarily at the same frequency as the light that is being reflected. The result is significant suppression of back reflection 124 at the input to first waveguide 104, as schematically shown by the shortening of the arrow representing input back-reflection 124 relative to the arrow for output back-reflection 120.

The following is a synopsis of experimental work by the present inventors demonstrating this effect. This experiment related to integrated continuous-wave isolators using the Kerr effect present in thin-film silicon-nitride ring resonators. The Kerr effect breaks the degeneracy between the clockwise and counterclockwise modes of the ring and allows for nonreciprocal transmission. These devices are fully passive and require no input besides the laser that is being isolated. As such, the only power overhead is the small insertion loss from coupling of the ring resonator. Additionally, many integrated optical systems that would benefit from isolators already have high-quality silicon-nitride or commensurate components and could easily integrate this type of isolator with CMOS-compatible fabrication.

To implement the devices, we use thin-film silicon nitride (<400 nm), as it has the potential for CMOS integration compatibility given the lower film stress present. In addition, the thin-silicon-nitride process allows for geometric dispersion properties that easily lead to a strong normal dispersion, allowing us to suppress spurious optical parametric oscillation.

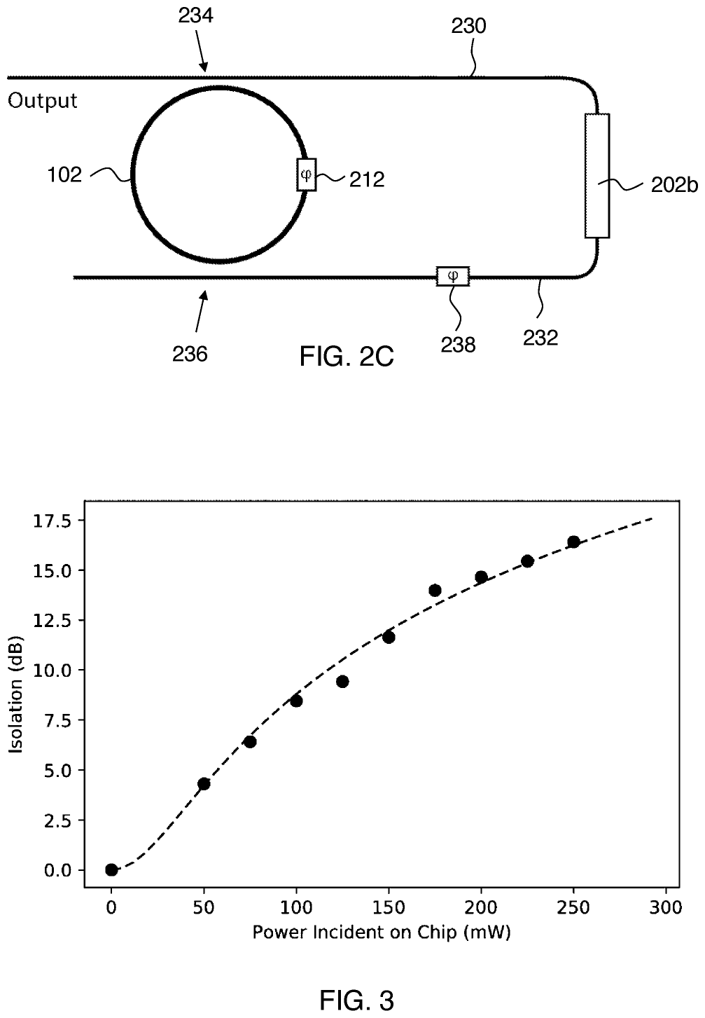

By varying the coupling of the ring resonators we can trade off insertion loss and isolation. As two examples, we demonstrate devices with a peak isolation of 23 dB with 4.6 dB insertion loss and isolation of 17 dB with a 1.3 dB insertion loss with 90 mW of optical power. As we are using an integrated photonics platform, we can reproducibly fabricate and cascade multiple isolators on the same chip, allowing us to demonstrate two cascaded isolators with an overall isolation ratio of 35 dB. Finally, we butt-couple a semiconductor laser-diode chip to the silicon-nitride isolators and demonstrate optical isolation in a system on a chip. FIG. 3 shows a representative result from this work, where the optical isolation depends on the incident power.

As indicated above, the main idea of this work is combining isolation via a non-reciprocal nonlinear resonator with a controlled feedback to provide a feedback-stabilized laser. Here a “feedback-stabilized laser” can be a laser oscillator (i.e., a DFB chip or the like) that is stabilized by a controlled optical feedback. Alternatively, it can be a true external cavity laser where the gain medium itself is a laser amplifier (e.g., a semiconductor optical amplifier chip with anti-reflection coated end faces) that requires the controlled optical feedback to form a laser cavity. In either case, the result is a laser with far lower linewidth (i.e., less noise) than one typically has from a semiconductor laser without feedback stabilization.

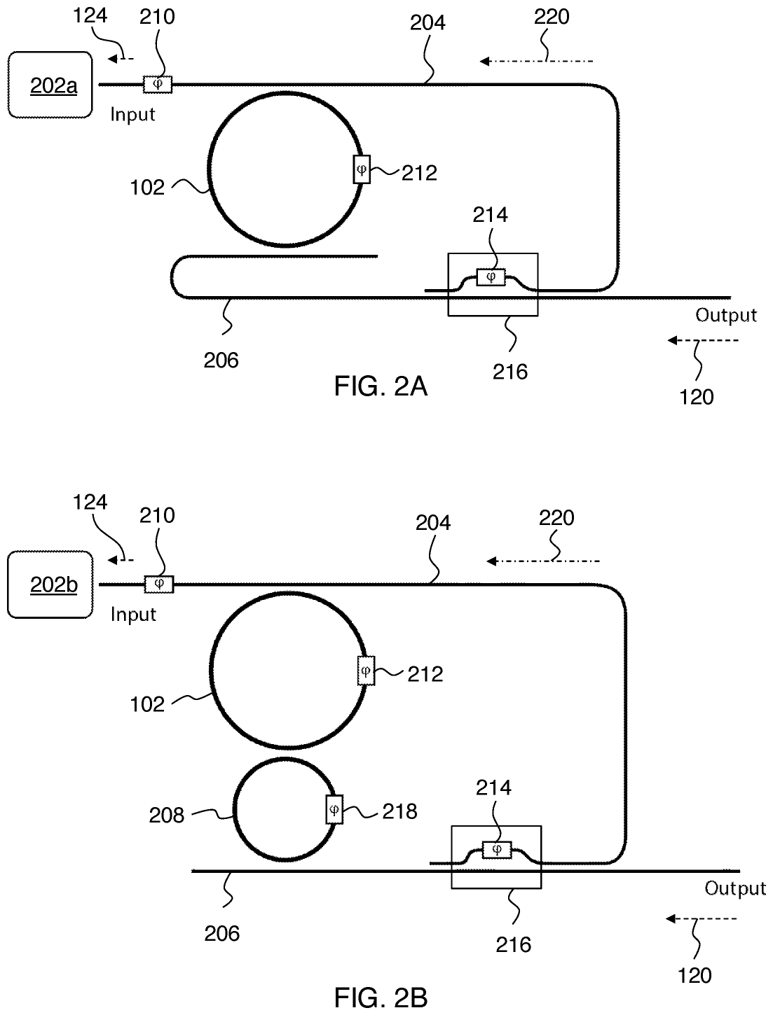

FIGS. 2A-C show three exemplary embodiments of the invention. Many other configurations are also possible in accordance with the general principles of providing both controlled feedback and isolation in an integration-friendly technology.

In the example of FIG. 2A, we directly couple a laser 202a to the on chip ring 102 via waveguide 204. Ring 102 is configured such that laser 202a is resonant with the ring and the majority of the power flows clockwise through the ring into the output port. The power in the ring splits the clockwise and counterclockwise modes and allows for power circulation and isolation of the laser. Part of the output power in waveguide 206 is then tapped with a Mach-Zehnder interferometer (MZI) or directional coupler 216 and sent to the through port of the ring as controlled feedback 220. As the ring is not resonant in this counterclockwise direction, controlled feedback 220 flows completely to the laser, completing the feedback loop. As controlled feedback 220 is heavily filtered by the high Q ring 102, it serves to stabilize the laser like in an external cavity laser setup.

A phase tuner 210 at the input or in the feedback path allows for the feedback phase to be varied for maximum stability. A phase tuner 214 and MZI 216 that links the output to the feedback path allows the feedback strength to be modulated to maximize stabilization and output power. This can also be replaced by a directional coupler or other fixed splitting structure if the desired feedback strength is a constant. Finally, a phase tuner 212 in the ring allows for the ring to be tuned onto resonance with the laser.

In the example of FIG. 2B, the same setup is used but now with simply a gain medium or semiconductor optical amplifier 202b as the input. To get this to lase in a single mode, we add a second ring 208 to act as a vernier filter and allow only one mode of the high Q ring to provide feedback. As before this both provides isolation and stabilization.

The vernier ring can operate in the linear regime and can be placed where it is in the diagram or only in the feedback path. By tuning the phase of the vernier filter with phase tuner 218 and the phase of the high Q ring with phase tuner 212, the frequency response of the feedback can be engineered to achieve single mode lasing. The additional phase tuners and MZI in the feedback path serve the same function as in the example of FIG. 2A.

Note that in the example of FIG. 2A we can replace laser 202a with amplifier 202b, provided that controlled feedback 220 is large enough for cavity round trip gain to exceed round trip loss (i.e., the usual lasing condition for an external cavity laser). Similarly, the dual-ring embodiment of FIG. 2B can be modified to replace amplifier 202b with laser 202a.

Another variant of the example of FIG. 2B is adding more resonators. We can cascade multiple rings to achieve higher isolation (e.g., as demonstrated in the isolator work). This gives an exponential increase in the isolation with the number of rings. As the photon lifetime will only be additive when multiple rings are present, the lifetime will increase linearly with the number of rings, and thus the theoretical linewidth reduction will increase quadratically. In practice the isolation will indeed increase exponentially, but the linewidth will likely only reduce until some limit is hit (could be thermo-refractive noise or technical noise).

Accordingly, an exemplary embodiment of the invention is an apparatus including:
a laser gain medium;
a first optical ring resonator optically coupled to the laser gain medium, where an output optical path from the laser gain medium to an output of the feedback stabilized laser includes the first optical ring resonator; and
a feedback path configured to return a predetermined fraction (e.g., 220 on FIGS. 2A-B) of output optical power to the laser gain medium, whereby a feedback-stabilized laser is provided.

Here the first optical ring resonator is a nonlinear resonator having unidirectional coupling to the laser gain medium such that back-reflection into the output of the feedback stabilized laser is suppressed by being off-resonance relative to the first optical ring resonator (i.e., reducing output back-reflection 120 to input back-reflection 124 as described above in connection with FIG. 1).

Along with isolating and stabilizing the laser, this topology allows for the turn-key startup of the full device, which is often difficult to achieve in resonant systems. Upon laser startup, as long as the laser frequency is relatively close to a cavity mode, the laser is pulled into lock with the ring with minimal effect on total lasing power. Even if the ring heats up due to a higher coupling, the laser can remain locked. This is in stark contrast to a resonant isolator used without an injection locking feedback: there the laser must be actively tuned onto the resonance, or the transmission will reduce dramatically. Accordingly, a startup sequence for the apparatus can achieve resonance passively, without the use of any active locking method.

Preferably the predetermined fraction is in a range from 1% to 99% of output power. Preferably, the back-reflection suppression provided by the optical ring resonator is 15 dB or more.

The feedback path can include a directional coupler configured to tap the predetermined fraction of output power and to provide the predetermined fraction of output power to the laser gain medium.

The laser gain medium can be configured as a laser oscillator capable of oscillating without receiving the predetermined fraction of output optical power as feedback. Alternatively, the laser gain medium can be configured as a laser amplifier incapable of oscillating without receiving the predetermined fraction of output optical power as feedback.

The output optical path can include a second optical ring resonator configured to provide vernier control of an output lasing mode (e.g., the example of FIG. 2B with second ring resonator 208 being linear).

The output optical path can include a second optical ring resonator configured to provide further suppression of back-reflection (e.g., the example of FIG. 2B with second ring resonator 208 being nonlinear). Back-reflection suppression provided by the first optical ring resonator combined with the second optical ring resonator is preferably 30 dB or more. As indicated above, further resonators can be added to further increase isolation.

In the example of FIG. 2C, the gain medium 202b is placed inside the feedback path, and the ring is coupled more strongly to one waveguide than the other (asymmetry in couplings 234 and 236). This allows the system to spontaneously lase only in one direction. Additionally, due to the mode splitting in the ring, any back reflected power will travel only once through the gain medium, providing isolation.

By making the coupling from the ring stronger on one side than the other (for example with a larger gap), the mode splitting from potential lasing will be stronger in one direction than the other. The phase tuner 212 in the ring and phase tuner 238 in the feedback path can then be used to made the feedback (and gain) path resonant with a single split ring mode. This will cause the setup to deterministically lase in the desired direction. Additionally, a vernier filter as in the example of FIG. 2B can be added to aid in single mode lasing.

Accordingly, an embodiment corresponding to the example of FIG. 2C has the laser gain medium 202b optically coupled at opposite ends to a first waveguide 230 and to a second waveguide 232, where the first and second waveguides are coupled to the first optical ring resonator to form a unidirectional ring optical path passing through the laser gain medium, the first optical ring resonator and the first and second waveguides (e.g., an overall counter-clockwise propagation path on FIG. 2C).

In this example, coupling 234 of the first waveguide 230 to the first optical ring resonator 102 is preferably larger than coupling 236 of the second waveguide 232 to the first optical ring resonator 102. Here the feedback path includes the second waveguide 232. Note that an output back-reflection in this configuration is not significantly attenuated before it reaches gain medium 202b. Instead, the undesirable effect of back-reflection on laser stability is mitigated by the high intracavity loss of clockwise propagating radiation in the configuration of FIG. 2C.

FIG. 3 shows measured isolation performance of a nonlinear ring resonator.

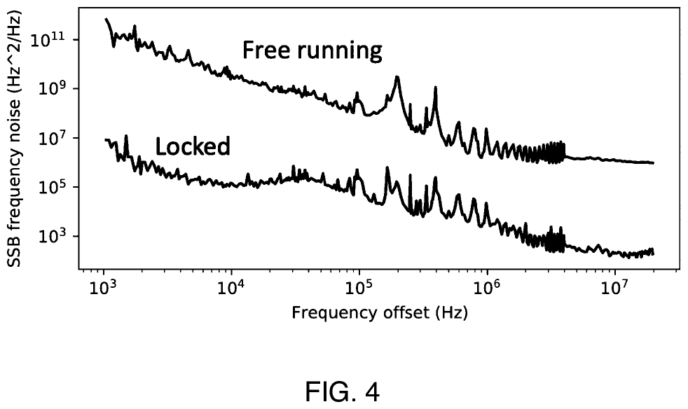

FIG. 4 shows measured laser noise suppression in an embodiment of the invention. Laser phase noise suppression of 20 dB or more is observed in this experiment. The experimental configuration here is that of FIG. 2A where laser 202a is a DFB (distributed feedback) semiconductor laser, and ring 102 is as described in connection with FIG. 1. The controlled feedback level used for this result was roughly 50%.

1. Apparatus comprising:
a laser gain medium;
a first optical ring resonator optically coupled to the laser gain medium, wherein an output optical path from the laser gain medium to an output of the feedback stabilized laser includes the first optical ring resonator; and
a feedback path configured to return a predetermined fraction of output optical power to the laser gain medium, whereby a feedback-stabilized laser is provided;
wherein the first optical ring resonator is a nonlinear resonator having unidirectional coupling to the laser gain medium such that back-reflection into the output of the feedback stabilized laser is suppressed by being off-resonance relative to the first optical ring resonator.

2. The apparatus of claim 1, wherein the output optical path includes a second optical ring resonator configured to provide vernier control of an output lasing mode.

3. The apparatus of claim 1, wherein the output optical path includes a second optical ring resonator configured to provide further suppression of back-reflection.

4. The apparatus of claim 3, wherein back-reflection suppression provided by the first optical ring resonator combined with the second optical ring resonator is 30 dB or more.

5. The apparatus of claim 1, wherein the feedback path includes a directional coupler configured to tap the predetermined fraction of output power and to provide the predetermined fraction of output power to the laser gain medium.

6. The apparatus of claim 1, wherein the laser gain medium is optically coupled at opposite ends to a first waveguide and a second waveguide, wherein the first and second waveguides are coupled to the first optical ring resonator to form a unidirectional ring optical path passing through the laser gain medium, the first optical ring resonator and the first and second waveguides.

7. The apparatus of claim 6, wherein a coupling of the first waveguide to the first optical ring resonator is larger than a coupling of the second waveguide to the first optical ring resonator, and wherein the feedback path includes the second waveguide.

8. The apparatus of claim 1, wherein the laser gain medium is configured as a laser oscillator capable of oscillating without receiving the predetermined fraction of output optical power as feedback.

9. The apparatus of claim 1, wherein the laser gain medium is configured as a laser amplifier incapable of oscillating without receiving the predetermined fraction of output optical power as feedback.

10. The apparatus of claim 1, wherein a back-reflection suppression provided by the optical ring resonator is 15 dB or more.

11. The apparatus of claim 1, wherein a startup sequence for the apparatus achieves resonance passively, without the use of any active locking method.

12. The apparatus of claim 1, wherein the predetermined fraction is in a range from 1% to 99% of output power.
